(19) United States
(12) Patent Application Publication
(10) Pub. No.: US 2008/0009139 A1
(43) Pub. Date: Jan. 10, 2008

(54) Structure in a substrate for the manufacturing of a semiconductor device and process for manufacturing of a semiconductor device

(76) Inventors: Thomas Hecht, Dresden (DE); Kristin Schupke, Dresden (DE); Kevin Bauer, Dresden (DE); Steffen Mueller, Dresden (DE); Henry Bernhardt, Dresden (DE)

Correspondence Address: SLATER & MATSIL LLP, 17950 PRESTON ROAD, SUITE 1000, DALLAS, TX, 75252, US

(21) Appl. No.: 11/481,419

(22) Filed: Jul. 5, 2006

(51) Int. Cl. H01L 21/302; H01L 21/461

(52) U.S. Cl. 438/705

(57) ABSTRACT

A structure in a substrate for the manufacturing of a semiconductor device, wherein a first material and at least one second material are to be etched by at least one etching medium, wherein the at least one second material has a higher etch rate for the at least one etching medium relative to the first material. The at least one second material occupies a space which is at least at one side adjacent to the first material so that an additional etching access to the first material is prepared when at least one etching medium etches the first and the second material.

### TECHNICAL FIELD

The present invention relates generally to a system and method for the manufacturing of a semiconductor device, and more particularly to a system and method for faster etching of material in a semiconductor device.

### BACKGROUND

In the manufacturing of semiconductor devices, such as DRAM-chips, microelectromechanical systems, optical devices or microprocessors, it is often necessary to remove some material from a substrate. This is often performed by wet or dry etching processes known in the art.

In both cases, the etching is a time consuming process since the etch medium must react with the material to be removed. Since many structures used in modern semiconductor devices have high aspect ratios, etching deep into the substrate requires considerable time. Since the processing time of the substrates influences the total throughput of a plant, making the processing time efficient is an issue. Furthermore, long removal times may cause etching of other materials, which are not supposed to be etched.

### SUMMARY OF THE INVENTION

Embodiment of the invention are concerned with a structure in a substrate for the manufacturing of a semiconductor device. A first material and at least one second material are to be etched by at least one etching medium. The at least one second material has a higher etch rate for the at least one etching medium relative to the first material. The at least one second material occupies a space that is at least at one side adjacent to the first material so that an additional etching access to the first material is prepared when at least one etching medium etches the first and the second material.

Furthermore, embodiments of the invention are concerned with a process for manufacturing a semiconductor device. A first material and at least one second material are deposited in a space within a substrate. The at least one second material has a higher etch rate relative to the first material. The at least one second material occupies a space that is at least at one side adjacent to the first material so that an additional etching access to the first material is formed when the first material and the second material are subjected to at least one etching medium.

With this structure and process, embodiments of the invention provide for a means that allows for a faster etching of material in a substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A to 1C schematically show three different process steps in a first embodiment of the process with a deep trench structure using an embodiment of the structure according to the invention;

FIGS. 2A to 2C schematically show a first variation of the first embodiment depicted in FIGS. 1A to 1C;

FIGS. 3A to 3C schematically show a second variation of the first embodiment depicted in FIGS. 1A to 1C;

FIGS. 4A to 4C schematically show three different process steps in a second embodiment of the process for a MEMS structure using an embodiment of the structure according to the invention;

FIGS. 5A to 5C schematically show a first variation of the second embodiment depicted in FIGS. 4A to 4C;

FIGS. 6A to 6C schematically show a second variation of the second embodiment depicted in FIGS. 4A to 4C; and

FIGS. 7A to 7C show microscopic images of three embodiments of the invention with different widths and additional etching accesses.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

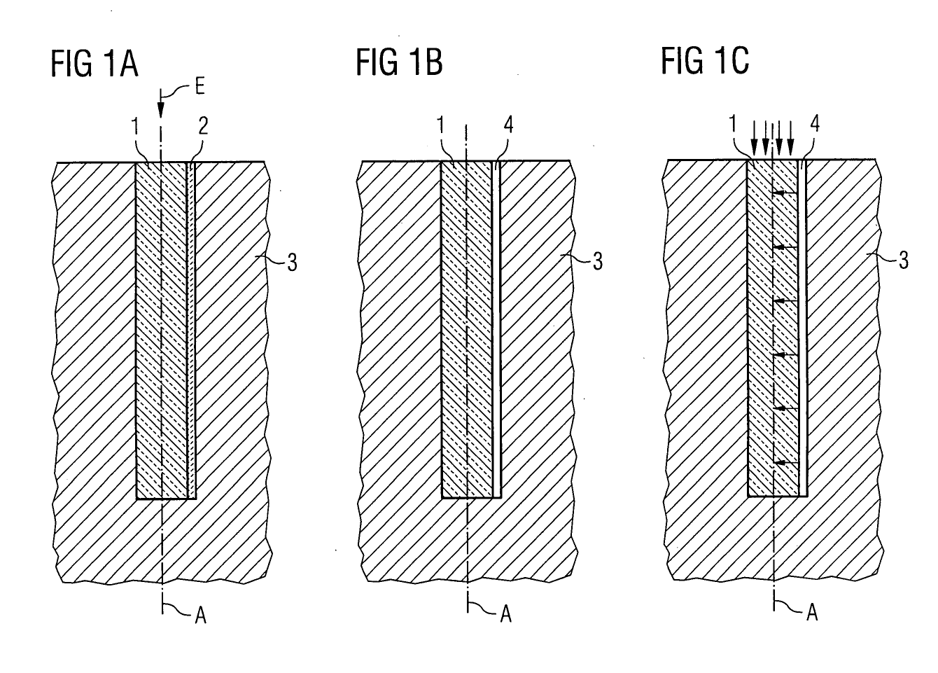

In FIGS. 1A to 1C, a first embodiment of the process according to the invention and the structure in a substrate 3 according to the invention are shown. The substrate 3 in this embodiment is a silicon wafer used in the production of semiconductor devices such as DRAM (or other memory) chips, microprocessors or microelectromechanical systems (MEMS). In principle, materials other than silicon can be chosen as substrate 3, such as germanium or any III-V semiconductor material.

The task depicted in FIGS. 1A to 1C is the etching of a depression, for example, a deep trench structure in the silicon wafer 3. The deep trench structure as used in the production for DRAM chips is chosen only as an example. In principle, other depressions in a substrate 3 can be processed according to the present invention.

In the processing of a deep trench structure, the trench is regularly filled with some material (sacrificial material), which is removed in a subsequent etching step. A non-limiting example of a first material 1 is a mold-oxide in a stacked capacitor structure. Alternatively, a similar structure can be used for a trench capacitor. Both embodiments are examples with oxides in a three-dimensional capacitor structure.

In FIG. 1A the deep trench is filled with a first material 1 and a second material 2. The second material 2 in the depicted embodiment is a relatively thin lining on the right side of the trench. The thickness of the lining of the second material 2 in this embodiment is approximately 2 nm. The aspect ratio of the deep trench structure can be between about 10 and about 70. The axis A indicates the long axis of the deep trench structure.

For this embodiment of the invention, the etching rate of the first material 1 is much lower than the etching rate of the second material 2. It is advantageous if the etching rate of the at least one second material is more than twice as high, especially between three and five times higher, and even more preferably ten times higher, than the etching rate of the first material for a given etching medium.

In the described embodiment (FIGS. 1A to 1C), the first material 1 is Si₂O and the second material 2 is Al₂O₃. The etching of the materials is performed in a two-step process for producing a stacked capacitor, i.e., the first etching is performed with hot H₃PO₄ selectively etching the second material. The second etching is performed with DHF (diluted HF), which etches the SiO₂.

An alternative embodiment of the invention only uses one etching medium. Where the first material 1 is silicon nitride (e.g., Si₂N₄) and the second material 2 is Al₂O₃, both could be etched with H₃PO₄. The etching rate of the first material 1 is much lower than the etching rate of the second material 2.

An etching medium etches the first material 1 and the second material 2 in the direction of arrow E. In this embodiment the etching direction E is parallel to the long axis A of the deep trench structure.

Since the etching is highly selective towards the second material 2, the second material 2 is rapidly etched away, while the first material 1 is basically not etched at all.

In FIG. 1B the result after the complete etching of the second material is shown. By removing the second material 2, a vertical narrow (2 nm) space 4 has been created providing an additional etching front parallel to a wall of the deep trench structure.

In FIG. 1C the etching fronts at the top of the first material 1 and the right side of the first material 1 are indicated by small arrows. This shows that the vertical space 4 gives additional access to an etching medium for etching the first material 1.

By producing a structure with an additional etching access 4, the etching surface for the first material 1 is enlarged so that the etching of the first material 1 by the same or a different etching medium can be effected much faster.

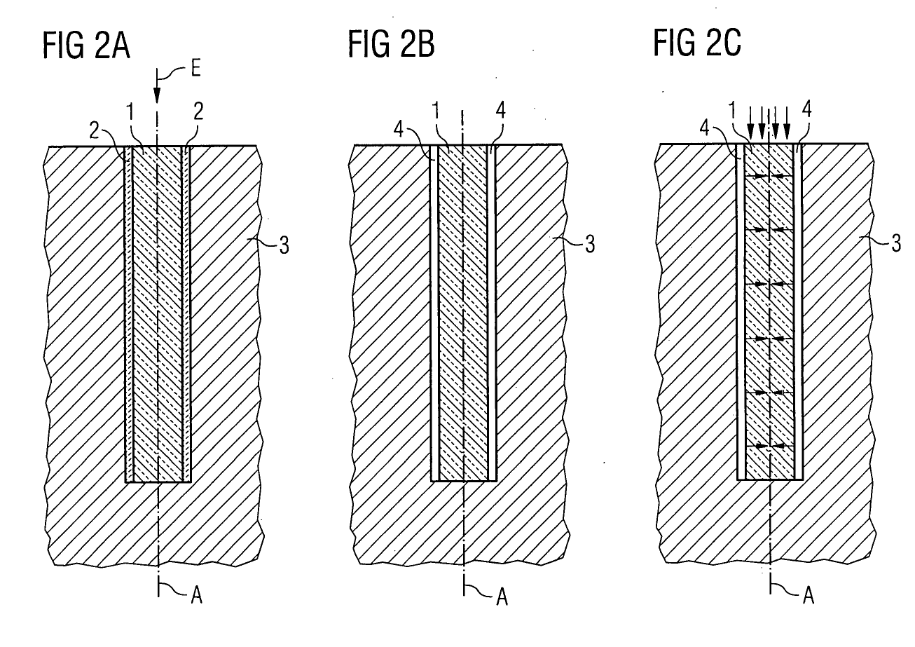

In FIGS. 2A to 2C a variation of the first embodiment depicted in FIGS. 1A to 1C is shown. Since the basic process steps and the structure are the same, reference is made to the above description.

Unlike the first embodiment shown in FIG. 1A, the deep trench structure is here filled with a first material 1 and a second material 2, the second material 2 being positioned on both sides of (e.g., surrounding) the first material 1. After the etching away of the second material 2 as in the first embodiment, the first material 1 is flanked by two spaces 4 (or a single annular space) creating additional etching access (FIG. 2B). As depicted in FIG. 2C, the etching of the first material 1 is effected with three etching fronts as indicated by arrows, one front on each the side and one front on top of the first material 1.

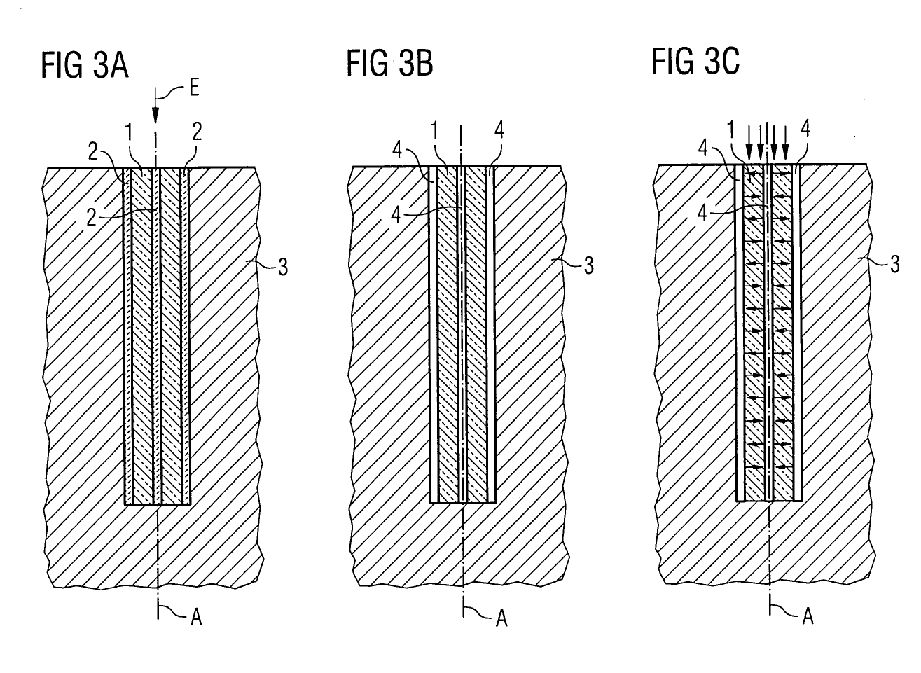

In FIGS. 3A to 3C, a further variation of the first embodiment is depicted, so that reference is made to the description above. To increase the etching front area, in the embodiment according to FIG. 3A, the first material is not only lined with the second material 2 as in FIG. 2A but also has one internal section which is filled with second material 2 (see FIG. 3A). After selectively etching away the second material 2, three additional etching accesses 4 are created (FIG. 3B). Consequently, five etching fronts are present for etching the first material 1 (FIG. 3C), i.e., four vertical fronts and one front on the top. In this embodiment at least one second material 2 is positioned in a space within the first material 1 so that a top side of the at least one second material 2 is exposed to the at least one etching medium (see FIG. 3B).

In an alternate embodiment, not shown, the central region of the second material 2 can be included without including the outer regions. In other words, the material 1 would abut the sidewalls of the substrate 3 in that example.

If more than one space is filled with a second material 2, like in FIG. 2A or FIG. 3A, it is not mandatory that the second materials 2 used be identical. For the embodiment shown in FIG. 3A, it is, for example, possible that the lining of the sides of the deep trench structure is one second material 2, and the second material 2 internal to the first material 1 is of a different kind. Both second materials 2 should have a much higher etch rate than the first material 1 for a given etching medium.

In any of the illustrated embodiments, the function of materials 1 and 2 could be reversed so that material 1 has a higher etching rate than the material 2. This change would affect which material is removed first to expose the other material. Thicknesses of the various materials can be varied accordingly.

In all embodiments described above, the interface between the first material 1 and the second material 2 is essentially parallel to a wall of the depression, e.g., the wall of the deep trench structure, i.e., the first material and the at least one second material are positioned in a depression essentially parallel to the long axis of the depression.

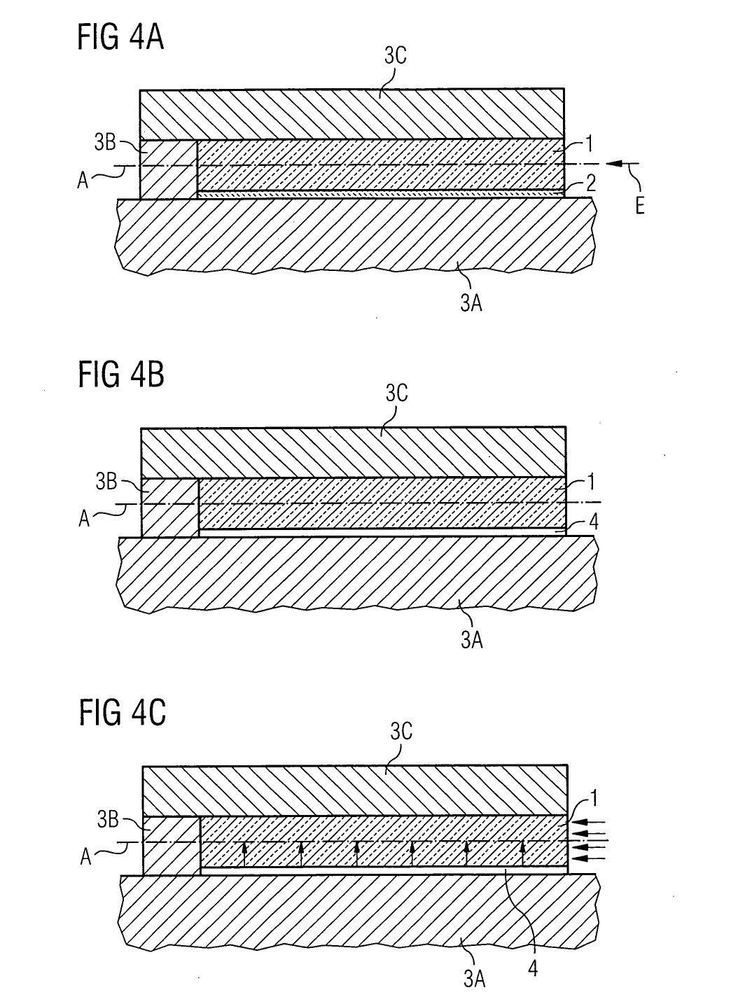

In the second embodiment and its variations shown in FIGS. 4, 5 and 6, the same principles are applied to a different structure, i.e., a structure where the silicon substrate 3A and structures 3B and 3C on top of the silicon substrate 3A are not etched from the top but from the side. Such structures occur, for example, in the manufacturing of MEMS, in which a silicon part 3C has to be removed from a basis (here the silicon substrate 3A), i.e., sacrificial material is located under the silicon part. Of course, the region 3A need not be a bulk substrate.

In FIG. 4A the silicon material 3C for a silicon part (e.g., a toothed wheel or cantilever) is located on top of a cavity that is filled by a first material 1 and a second material 2. A residual part 3B connects the silicon part 3C with the silicon substrate 3A. The cavity has its long axis oriented essentially parallel to the substrate. Materials other than silicon could also be used.

The task is to remove the first and second materials 1 and 2, so that the silicon part remains horizontally for further processing. The etching direction is indicated by arrow E, i.e., the etching of the cavity is coming from the right and progresses toward the left. The long axis A of the cavity is shown in FIG. 4.

The first and second materials 1 and 2 might differ from the first examples (FIGS. 1 to 3) but they have the same properties as related to their relative etching rate, e.g., the etching rate of the first material 1 being much lower than the etching rate of the second material 2.

The etching process for this embodiment is similar to the etching employed in the embodiments shown in FIG. 1. The one thin (e.g., 2 nm) lining of the second material 2 is rapidly etched away (FIG. 4B). After that, the same etching medium or a different etching medium is used to etch the first material 1 from underneath the newly created etching access 4 and from the right side. The etch fronts are indicated by small arrows.

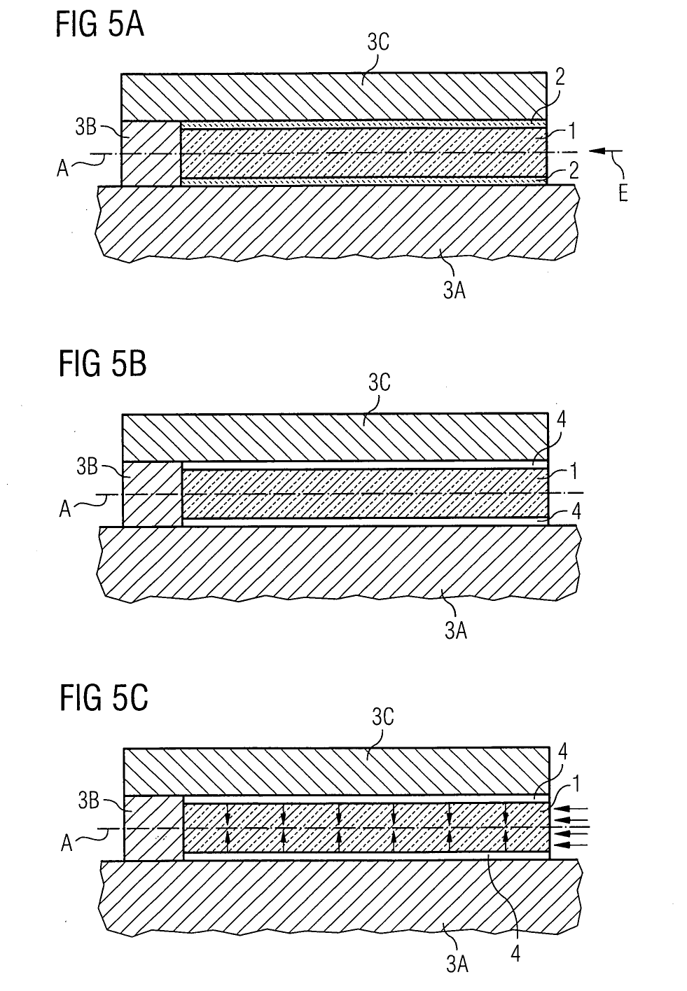

Like in FIGS. 2 and 3, the embodiment according to FIG. 4 can be modified. In FIGS. 5A to 5C, an embodiment is shown which is comparable to the one depicted in FIGS. 2A to 2C, i.e., the first material 1 is here lined on top and underneath with a second material 2. As mentioned above, the second material 2 in those two linings do not have to be identical but for reasons of process economy it is advantageous if they are of the same material.

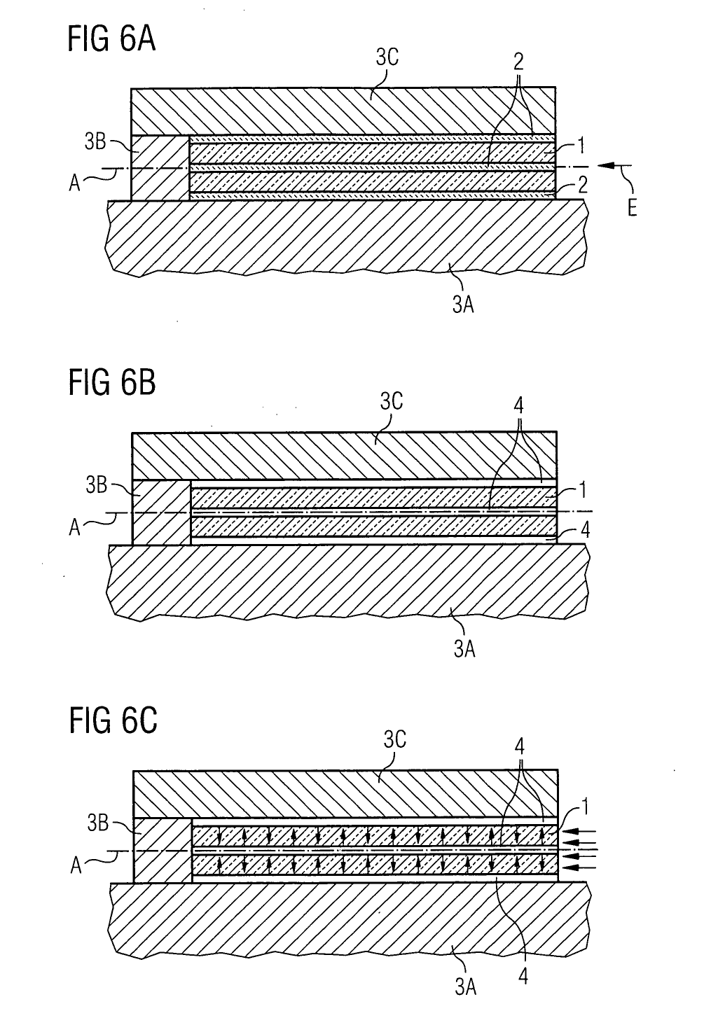

In FIGS. 6A to 6C, an embodiment is described which is comparable to the one described in FIGS. 3A to 3C, i.e., internal to the first material 1, a space is filled with second material 2.

The etching of the embodiments of FIGS. 5 and 6 is performed like the one in FIG. 4, i.e., from the right to the left. The more spaces that are occupied by the second material, the more etching fronts (indicated by small arrows) that are created. The more etching fronts, the faster the etching is performed.

In all embodiments, at least one second material 2 was deposited adjacent to a wall of a depression or a cavity. This does not necessarily have to be the case. As noted above, it is also possible for the depression or the cavity to be filled with a first material 1, the second material 2 only being positioned internally to the first material as shown, for example, in FIGS. 3A or 6A.

In the embodiments, there is at least one interface between the first material 1 and the second material 2, both materials having the relative etching rate properties described above. The second material 2 occupies a space which is at least at one side adjacent to the first material 1 so that an additional etching access 4 to the first material 1 is prepared when at least one etching medium etches the first and the second materials 1 and 2.

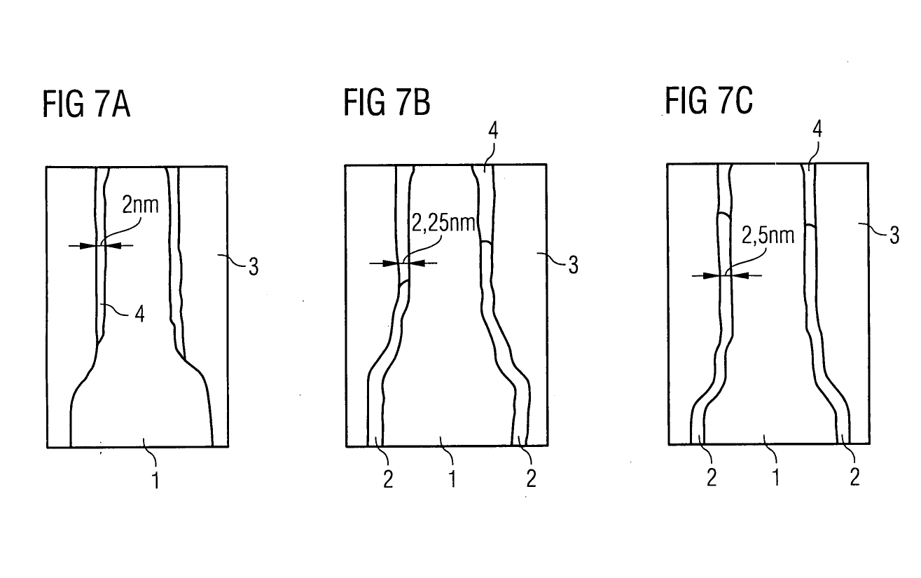

In FIGS. 7A to 7C, the effect of the additional etching access is demonstrated in the etching of a bottle trench structure. FIGS. 7A to 7C depict microscopic images showing cross-sections of the upper part of the bottle trench structure within a substrate 3. A first material 1 fills the bottle trench structure. It is this first material 1 which will have to be removed. In FIG. 7A, a relatively thin (e.g., 2 μm) layer of a second material 2 is used. The second material 2 is here a lining of Al₂O₃, which is highly selective to the first material 1, here polysilicon.

FIGS. 7A to 7C show that for the purposes of this invention, i.e., the creation of an additional access for etching, it is advantageous to use as thin a layer of the second material 2 as possible. As can be seen, the etching of the second material 2 is improved with a sinking thickness of the second material 2. In FIG. 7C, the thickness is 2.5 nm. In FIG. 7B the thickness is 2.25 nm, and in FIG. 7A the thickness is 2 nm. FIGS. 7A to 7C show the etching progress after the same time interval. As can be seen, the etching progress is the least in FIG. 7C and the most in FIG. 7A.

For all the described embodiments, the at least one first material can be at least one of the group of silicon, amorphous silicon, polysilicon, SiO₂, Si₃N₄, low-k oxides and carbon-containing materials.

For all the described embodiments, the at least one second material is one of the group of Al₂O₃, hafnium oxide, zirconium silicon oxide and aluminum-silicon oxide.

For all the described embodiments, the at least one etching medium is one of the group of hot phosphoric acid, HFEG (hydrofluoric ethylene glycol), DHF (diluted HF) and BHF (buffered HF).

The person skilled in the art will recognize that the different embodiments described above can be combined to form new embodiments, all being in the scope of the present invention.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A structure for use in the manufacturing of a semiconductor device, the structure comprising:
a substrate having a recess disposed therein; and
a first material and at least one second material disposed in the recess, wherein the at least one second material has a higher etch rate for at least one etching medium relative to the first material, the at least one second material occupying a space adjacent to the first material so that an additional etching access to the first material is prepared when the at least one etching medium etches the first and the second material.

2. The structure according to claim 1, wherein the etching rate of the at least one second material is between three and five times higher than the etching rate of the first material.

3. The structure according to claim 1, wherein the first material and the at least one second material are positioned in the recess essentially parallel to a long axis of the recess.

4. The structure according to claim 1, wherein the first material comprises an oxide in a three-dimensional capacitor structure.

5. The structure according to claim 4, wherein the capacitor structure comprises a structure selected from the group consisting of a trench structure, a deep trench structure for a DRAM memory chip, and a stacked capacitor.

6. The structure according to claim 3, wherein an interface between the first material and the at least one second material is essentially parallel to a wall of the recess.

7. The structure according to claim 3, wherein the at least one second material is positioned on at least one wall of the recess.

8. The structure according to claim 3, wherein the at least one second material is positioned in at least one space within the first material with at least one top side of the at least one second material being exposed to the at least one etching medium.

9. The structure according to claim 1, wherein the recess has a long axis that is essentially parallel to an upper surface of the substrate.

10. The structure according to claim 9, wherein the recess is a structure for producing a part for a microelectromechanical (MEM) device.

11. The structure according to claim 10, wherein the part for the microelectromechanical device is one of a toothed wheel, an actuator and/or a cantilever.

12. The structure according to claim 9, wherein an interface between the first material and the at least one second material is essentially parallel to a wall of the recess.

13. The structure according to claim 9, wherein the at least one second material is positioned on at least one wall of the recess.

14. The structure according to claim 9, wherein the at least one second material is positioned in at least one space within the first material with at least one side of the at least one second material being exposed to the at least one etching medium.

15. The structure according to claim 1, wherein in the additional etching access for the first material is positioned so that the etching front is essentially perpendicular to the etching direction for the first material.

16. The structure according to claim 1, wherein the at least one second material comprises a layer with a thickness of less than 10 nm and more than 0.5 nm.

17. The structure according to claim 1, wherein the first material comprises at least one material selected from the group consisting of silicon, amorphous silicon, polysilicon, SiO₂, Si₃N₄, low-k oxides and carbon-containing materials.

18. The structure according to claim 1, wherein the at least one second material comprises at least one material selected from the group consisting of Al₂O₃, hafnium oxide, zirconium silicon oxide and aluminum-silicon oxide.

19. The structure according to claim 1, wherein the at least one etching medium is one of the group consisting of hot phosphoric acid, HFEG, DHF and BHF.

20. A structure in a substrate for the manufacturing of a semiconductor device, wherein a first material and at least one second material are to be etched by at least one etching medium, wherein the at least one second material has a higher etch rate for the at least one etching medium relative to the first material, and wherein the at least one second material is positioned space with at least one side adjacent to the first material for providing means for an additional etching access to the first material.

21. A process for manufacturing a semiconductor device, the process comprising:
depositing a first material and at least one second material in a space within a substrate, wherein the at least one second material has a higher etch rate relative to the first material;
etching the at least one second material selectively relative to the first material; and
etching the first material, wherein the etching of the at least one second material creates an additional etching access to the first material so that the first material is etched from the additional etching access after the at least one second material is etched.

22. The process according to claim 21, wherein the at least one second material has an etching rate that is more than twice as high as an etching rate of the first material for a first etching medium, wherein etching the at least one second material selectively relative to the first material is performed using the first etching medium.

23. The process according to claim 21, wherein the first material and the at least one second material are positioned in a depression essentially parallel to a long axis of the depression.

24. The process according to claim 23, wherein an interface between the first material and the at least one second material is essentially parallel to a wall of the depression.

25. The process according to claim 23, further comprising depositing the at least one second material on at least one wall of the depression.

26. The process according to claim 23, further comprising depositing the at least one second material in at least one space within the first material so that at least one top side of the at least one second material is exposed to an etching medium during the etching of the at least one second material.

27. The process according to claim 23, wherein the first material and the at least one second material are positioned in a cavity, wherein the cavity has a long axis that is essentially parallel to an upper surface of the substrate.

28. The process according to claim 27, wherein an interface between the first material and the at least one second material is essentially parallel to a wall of the cavity.

29. The process according to claim 27, wherein the at least one second material is formed on at least one wall of the cavity.

30. The process according to claim 27, wherein the at least one second material is formed in at least one space within the first material so that at least one side of the at least one second material is exposed to an etching medium during the etching of the at least one second material.

31. The process according to claim 27, wherein the additional etching access to the first material allows the etching front to be essentially perpendicular to the etching direction of the first material.

32. The process according to claim 27, wherein the at least one second material comprises a layer with a thickness of less than 5 nm.

33. The process according to claim 21, wherein the first material comprises at least one material selected from the group consisting of silicon, amorphous silicon, polysilicon, SiO₂, Si₃N₄, low-k materials and carbon-containing materials.

34. The process according to claim 21, wherein the at least one second material comprises at least one material selected from the group consisting of aluminum oxide, hafnium oxide, zirconium silicon oxide and aluminum-silicon oxide.

35. The process according to claim 21, wherein the etching medium is one of the group consisting of hot phosphoric acid, HFEG, DHF and BHF.

36. The process according to claim 21, wherein the semiconductor device comprises a DRAM chip or a microelectromechanical device.

37. The process according to claim 21, wherein the at least one second material is etched using a first etching medium and wherein the first material is etched using a second etching medium.
